(19) United States
(12) Patent Application Publication
(10) Pub. No.: US 2011/0057331 A1
(43) Pub. Date: Mar. 10, 2011

(54) THERMOSETTING DIE BONDING FILM, DICING DIE BONDING FILM AND SEMICONDUCTOR DEVICE

(76) Inventors: Miki Hayashi, Osaka (JP); Shumpei Tanaka, Osaka (JP); Kenji Oonishi, Osaka (JP); Yuuichirou Shishido, Osaka (JP); Kouichi Inoue, Osaka (JP)

(21) Appl. No.: 12/875,383

(22) Filed: Sep. 3, 2010

(30) Foreign Application Priority Data
Sep. 7, 2009 (JP) 2009-206174

(51) Int. Cl. H01L 23/52

(52) U.S. Cl. 257/783; 257/E23.141

(57) ABSTRACT

An object of the present invention is to provide a thermosetting die-bonding film with which a die-bonding film is suitably broken with a tensile force. The object is achieved by a thermosetting die-bonding, film at least having an adhesive layer that is used to fix a semiconductor chip to an adherend, in which the breaking energy per unit area is 1 J/mm² or less and the elongation at break is 40% or more to 500% or less at room temperature before thermal setting.

### BACKGROUND OF THE INVENTION

1. Field of the Invention

The present invention relates to a thermosetting die-bonding film used when a semiconductor element such as a semiconductor chip is adhered and fixed on an adherend such as a substrate or a lead frame. The present invention also relates to a dicing die-bonding film including the thermosetting die-bonding film and a dicing film layered to each other. The present invention also relates to a semiconductor device manufactured using the thermosetting die bond film or the dicing die bond film.

2. Description of the Related Art

Conventionally, silver paste has been used to bond a semiconductor chip to a lead frame or an electrode member in the step of producing a semiconductor device. The treatment for the sticking is conducted by coating a paste-form adhesive on a die pad of a lead frame, or the like, mounting a semiconductor chip on the die pad, and then setting the paste-form adhesive layer.

However, about the paste-form adhesive, the amount of the coated adhesive, the shape of the coated adhesive, and on the like are largely varied in accordance with the viscosity behavior thereof, a deterioration thereof, and on the like. As a result, the thickness of the formed paste-form adhesive layer becomes uneven so that the reliability in strength of bonding a semiconductor chip is poor. In other words, if the amount of the paste-form adhesive coated on an electrode member is insufficient, the bonding strength between the electrode member and a semiconductor chip becomes low so that in a subsequent wire bonding step, the semiconductor chip is peeled. On the other hand, if the amount of the coated paste-form adhesive is too large, this adhesive flows out to stretch over the semiconductor chip so that the characteristic becomes poor. Thus, the yield or the reliability lowers. Such problems about the adhesion treatment become particularly remarkable with an increase in the size of semiconductor chips. It is therefore necessary to control the amount of the coated paste-form adhesive frequently. Thus, the workability or the productivity is deteriorated.

In this coating step of a paste-form adhesive, there is a method of coating the adhesive onto a lead frame or a forming chip by an independent operation. In this method, however, it is difficult to make the paste-form adhesive layer even. Moreover, an especial machine or a long time is required to coat the paste-form adhesive. Thus, a dicing film which makes a semiconductor wafer to be bonded and held in a dicing step and further gives an adhesive layer, for bonding a chip, which is necessary for a mounting step is disclosed (see, for example, JP-A-60-57342).

This dicing film has a structure wherein a adhesive layer and an adhesive layer are successively laminated on a supporting substrate. That is, a semiconductor wafer is diced in the state that the wafer is held on the adhesive layer, and then the supporting substrate is extended; the chipped works are peeled together with the adhesive layer; the peeled works are individually collected; and further the chipped works are bonded onto an adherend such as a lead frame through the adhesive layer.

When a dicing die-bonding film including a dicing film and a die-bonding film laminated thereon is used and a semiconductor wafer is diced while being held by the die-bonding film, it is necessary to cut the die-bonding film and the semiconductor wafer at the same time. However, in a general dicing method using a diamond blade, it is necessary to reduce the cutting speed and costs are increased because there are potential problems such as adhesion of the die-bonding film with the dicing film due to heat that is generated during dicing, sticking of semiconductor chips due to generation of cutting scraps, and attachment of cutting scraps onto the side of the semiconductor chips.

In recent years, there have been proposed a method of obtaining individual semiconductor chips by forming grooves on the surface of a semiconductor wafer and then performing backside grinding (refer to Japanese Patent Application Laid-Open No. 2003-007649, for example) and a method of obtaining individual semiconductor chips by forming a reformed region on a scheduled dividing line on the semiconductor wafer by irradiation with a laser beam so that the semiconductor wafer can be easily dividable on the scheduled dividing line and then applying a tensile force thereto to break the semiconductor wafer (refer to Japanese Patent Application Laid-Open Nos. 2002-192370 and 2003-338467, for example). According to these methods, the generation of defects such as chipping can be reduced in the case where the semiconductor wafer is thin and the yield of the semiconductor chip can be improved by narrowing the kerf width.

It is necessary to break the die-bonding film by applying a tensile force to obtain individual semiconductor chips with a die-bonding film by the above-described method while the semiconductor wafer is being held by the die-bonding film. Accordingly, development of a die-bonding film that can be suitably broken by applying a tensile force has been desired.

### SUMMARY OF THE INVENTION

The present invention has been made in view of the above-described problems, and an object thereof is to provide a thermosetting die-bonding film and a dicing die-bonding film in which the die-bonding film can be suitably broken by applying a tensile force, and to provide a semiconductor device manufactured using the thermosetting die-bonding film or the dicing die-bonding film.

The present inventors have intensively studied about a thermosetting die-bonding film, and a dicing die-bonding film including the thermosetting die-bonding film and a dicing film layered to each other so as to solve the above conventional problems. As a result, it was found that the die-bonding film can be suitably broken by applying a tensile force by making the breaking energy per unit area be 1 J/mm² or less and the elongation at break be 40% or more to 500% or less at room temperature, and the present invention was completed.

That is, the thermosetting die-bonding film according to the present invention is a thermosetting die-bonding film at least having an adhesive layer that is used to fix a semiconductor chip to an adherend, wherein the breaking energy per unit area is 1 J/mm² or less and the elongation at break is 40% or more to 500% or less at room temperature before thermal setting.

According to the above-described configuration, the die-bonding film can be suitably broken with a tensile force by making the thermosetting die-bonding film (hereinafter sometimes referred to as the “die-bonding film”) have a breaking energy per unit area of 1 J/mm² or less and an elongation at break of 40% or more to 500% or less at room temperature. The “breaking energy” in the present invention can be obtained from the area under a stress-strain curve (refer to FIG. 9) that is obtained using a tensile test apparatus at a tensile speed of 0.5 m/min on a sample having a width of 10 mm, a distance between chucks of 20 mm, and a thickness of 5 to 250 μm. The “elongation at break” in the present invention can be obtained from (((distance between chucks at break (mm))−20)/20)×100.

In the above-described configuration, the adhesive layer contains an epoxy resin and a phenol resin as thermosetting resins and also contains an acrylic resin as a thermoplastic resin. When the total weight of the epoxy resin and the phenol resin is regarded as X and the weight of the acrylic resin is regarded as Y, the value of X/(X+Y) is preferably 0.3 or more and less than 0.9. The die-bonding film is more easily broken as the content of the epoxy resin and the phenol resin increases; however, tackiness to a semiconductor wafer decreases. Further, the die-bonding film is more difficult to crack during bonding and handling and the workability improves as the content of the acrylic resin increases; however, the breakage becomes more difficult. By making the value of X/(X+Y) be within the above-described range, the processability can be secured and the breakage can easily occur.

In the above-described configuration, at least one of the epoxy resin and the phenol resin preferably contains one type or more of a resin having a melting point of 50° C. or more. By containing a resin having a melting point of 50° C. or more, the die-bonding film can be more suitably broken with a tensile force.

In the above-described configuration, the adhesive layer contains an epoxy resin and a phenol resin as thermosetting resins, an acrylic resin as a thermoplastic resin, and a filler. When the total weight of the epoxy resin, the phenol resin, and the acrylic resin is regarded as A and the weight of the filler is regarded as B, the value of B/(A+B) is preferably 0.1 or more to 0.7 or less. With the value of B/(A+B) being 0.7 or less, the tensile storage modulus is prevented from becoming too large, and wettability and tackiness to the adherend can be maintained. With the value of B/(A+B) being 0.1 or more, the die-bonding film can be more suitably broken with a tensile force. That is, with the value of B/(A+B) being 0.1 or more, the die-bonding film is prevented from cracking before bonding to the semiconductor wafer, and the workability improves.

In the above-described configuration, the tensile storage modulus at −20 to 30° C. before thermal setting is preferably 0.1 to 10 GPa. With the tensile storage modulus being within this range, chipping can be prevented from occurring when dividing the semiconductor wafer at the scheduled dividing line after the irradiation with a laser beam. Further, positional deviation and scattering of the semiconductor chips can be prevented when the wafer is divided at the scheduled dividing line.

The dicing die-bonding film according to the present invention features that the thermosetting die-bonding film is laminated on the dicing film including a base and a pressure-sensitive adhesive layer laminated thereon to solve the problems.

The semiconductor device according to the present invention features that it is manufactured using the above-described thermosetting die-bonding film or the dicing die-bonding film to solve the problems.

### BRIEF DESCRIPTION OF THE DRAWINGS

FIG. 1 is a schematic sectional view showing a dicing die-bonding film according to one embodiment of the present invention;

FIG. 2 is a schematic sectional view showing a dicing die-bonding film according to another embodiment of the present invention;

FIG. 3 is a schematic sectional view for explaining one method of manufacturing a semiconductor device according to the present embodiment;

FIG. 4 is a schematic sectional view for explaining the method of manufacturing a semiconductor device according to the present embodiment;

FIGS. 5A and 5B are schematic sectional views for explaining the method of manufacturing a semiconductor device according to the present embodiment;

FIG. 6 is a schematic sectional view for explaining the method of manufacturing a semiconductor device according to the present embodiment;

FIGS. 7A and 7B are schematic sectional views for explaining another method of manufacturing a semiconductor device according to the present embodiment;

FIG. 8 is a schematic sectional view for explaining the different method of manufacturing a semiconductor device according to the present embodiment; and

FIG. 9 is a drawing showing one example of a stress-strain curve.

### DESCRIPTION OF THE EMBODIMENTS

(Dicing Die-Bonding Film)

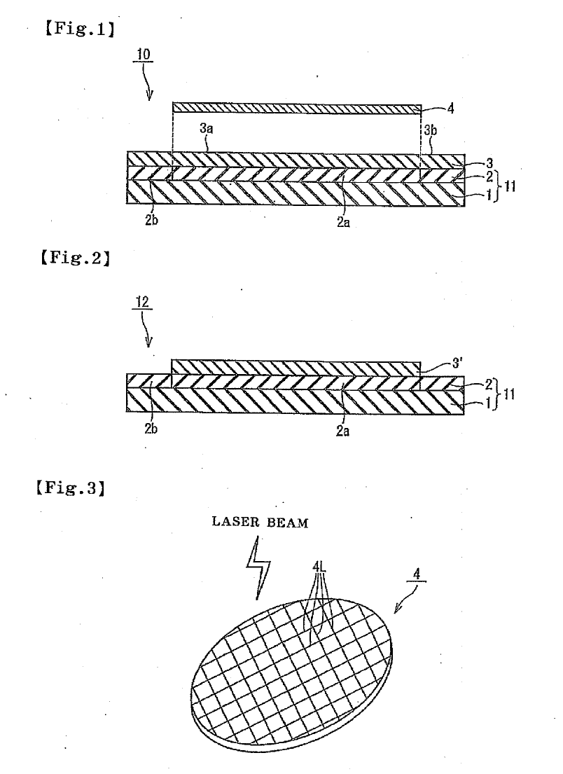

The thermosetting die-bonding film of the present invention is explained below using a dicing die-bonding film that is laminated integrally with a dicing film as an example. FIG. 1 is a schematic sectional view showing a dicing die-bonding film according to one embodiment of the present invention. FIG. 2 is a schematic sectional view showing a dicing die-bonding film according to another embodiment of the present invention.

As shown in FIG. 1, a dicing die-bonding film 10 has a constitution in which a die-bonding film 3 is layered on a dicing film 11. The dicing film 11 is constituted by layering a pressure-sensitive adhesive layer 2 on a base material 1, and the die-bonding film 3 is provided on the adhesive layer 2. As shown in FIG. 2, the present invention may have a constitution such that a die-bonding film 3′ is formed only at the portion to which workpieces are laminated.

The base material 1 preferably has ultraviolet transmissivity and is a base body for strength of the dicing die-bonding films 10 and 12. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene(meth)acrylic acid copolymer; an ethylene(meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper.

Further, the material of the base material 1 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 2 and the die-bonding films 3, 3′ is reduced by thermally shrinking the base material 1 after dicing, and the recovery of the semiconductor chips (a semiconductor element) can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base material 1 in order to improve adhesiveness, holding properties, etc. with the adjacent layer. The same type or different type of base material can be appropriately selected and used as the base material 1, and abase material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the base material 1 in order to give an antistatic function to the base material 1. The base material 1 may be a single layer or a multi layer of two or more types.

The thickness of the base material 1 can be appropriately decided without limitation particularly. However, it is generally about 5 to 200 μm.

The pressure-sensitive adhesive layer 2 is constituted by containing a ultraviolet curable pressure sensitive adhesive. The ultraviolet curable pressure sensitive adhesive can easily decrease its adhesive strength by increasing the degree of crosslinking by irradiation with ultraviolet. By radiating only a part 2a corresponding to the semiconductor wafer pasting part of the pressure-sensitive adhesive layer 2 shown in FIG. 2, a difference of the adhesive strength to another part 2b can be also provided.

Further, by curing the ultraviolet curable pressure-sensitive adhesive layer 2 with the die-bonding film 3′ shown in FIG. 2, the part 2a in which the adhesive strength is remarkably decreased can be formed easily. Because the die-bonding film 3′ is pasted to the part 2a in which the adhesive strength is decreased by curing, the interface of the part 2a of the pressure-sensitive adhesive layer 2 and the die-bonding film 3′ has a characteristic of being easily peeled during pickup. On the other hand, the part not radiated by ultraviolet rays has sufficient adhesive strength, and forms the part 2b.

As described above, in the pressure-sensitive adhesive layer 2 of the dicing die-bonding film 10 shown in FIG. 1, the part 2b formed by a non-cured ultraviolet curable pressure sensitive adhesive sticks to the die-bonding film 3, and the holding force when dicing can be secured. In such a way, the ultraviolet curable pressure sensitive adhesive can support the die-bonding film 3 for fixing the semiconductor chip onto an adherend such as a substrate with good balance of adhesion and peeling. In the pressure-sensitive adhesive layer 2 of the dicing die-bonding film 11 shown in FIG. 2, a dicing ring can be fixed to the part 2b.

The ultraviolet curable pressure sensitive adhesive that is used has a ultraviolet curable functional group of a radical reactive carbon-carbon double bond, etc., and adherability. Examples of the ultraviolet curable pressure sensitive adhesive are an added type ultraviolet curable pressure sensitive adhesive in which a ultraviolet curable monomer component or an oligomer component is compounded into an acryl pressure sensitive adhesive or a rubber pressure sensitive adhesive.

The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Specific examples of the acryl polymers include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl(meth)acrylate, carboxypentyl(meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxylmethylcyclohexyl)methyl(meth)acrylate; sulfonic acid group containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer(s) to be used is preferably 40% or less by weight of all the monomer components.

For crosslinking, the acrylic polymer can also contain multifunctional monomers if necessary as the copolymerizable monomer component. Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy(meth)acrylate, polyester(meth)acrylate, urethane(meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the above acryl polymer can be performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight average molecular weight of 300000 or more, particularly 400000 to 30000000 is as a main component are preferable from such viewpoint, the pressure-sensitive adhesive can be made to be an appropriate cross-linking type with an internal cross-linking manner, an external cross-linking manner, etc.

To increase the number-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. Generally, the crosslinking agent is preferably incorporated in an amount of about 5 parts by weight or less based on 100 parts by weight of the base polymer. The lower limit of the crosslinking agent is preferably 0.1 parts by weight or more. The pressure-sensitive adhesive may be blended not only with the components described above but also with a wide variety of conventionally known additives such as a tackifier, and aging inhibitor, if necessary.

Examples of the ultraviolet curable monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the ultraviolet curable oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the ultraviolet ray curable monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 40 to 150 parts by weight based on 100 parts by weight of the base polymer such as an acryl polymer constituting the pressure sensitive adhesive.

Further, besides the added type ultraviolet curable pressure sensitive adhesive described above, the ultraviolet curable pressure sensitive adhesive includes an internal ultraviolet curable pressure sensitive adhesive using an acryl polymer having a radical reactive carbon-carbon double bond in the polymer side chain, in the main chain, or at the end of the main chain as the base polymer. The internal ultraviolet curable pressure sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive overtime.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radial ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with any one of the hydroxyl-containing monomers exemplified above, or an ether compound such as 2-hydroxyethyl vinyl ether, 4-hydroxybutyl vinyl ether or diethylene glycol monovinyl ether.

The intrinsic type radial ray curable adhesive may be made only of the above-mentioned base polymer (in particular, the acrylic polymer), which has a carbon-carbon double bond. However, the above-mentioned radial ray curable monomer component or oligomer component may be incorporated into the base polymer to such an extent that properties of the adhesive are not deteriorated. The amount of the radial ray curable oligomer component or the like is usually 30 parts or less by weight, preferably from 0 to 10 parts by weight for 100 parts by weight of the base polymer.

In the case that the radial ray curable adhesive is cured with ultraviolet rays or the like, a photopolymerization initiator is incorporated into the adhesive. Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

Further, examples of the ultraviolet curing type pressure-sensitive adhesive which is used in the formation of the pressure-sensitive adhesive layer 2 include such as a rubber pressure-sensitive adhesive or an acryl pressure-sensitive adhesive which contains an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine, and an onium salt compound, which are disclosed in JP-A No. 60-196956. Examples of the above addition-polymerizable compound having two or more unsaturated bonds include such as polyvalent alcohol ester or oligoester of acryl acid or methacrylic acid and an epoxy or a urethane compound.

The method of forming the part 2a in the pressure-sensitive adhesive layer 2 includes a method of forming the ultraviolet curable pressure-sensitive adhesive layer 2 on the base material 1 and then radiating the part 2a with ultraviolet partially and curing. The partial ultraviolet irradiation can be performed through a photo mask in which a pattern is formed which is corresponding to a part 3b, etc. other than the semiconductor wafer pasting part 3a. Further, examples include a method of radiating in a spot manner and curing, etc. The formation of the ultraviolet curable pressure-sensitive adhesive layer 2 can be performed by transferring the pressure-sensitive adhesive layer provided on a separator onto the base material 1. The partial ultraviolet curing can be also performed on the ultraviolet curable pressure-sensitive adhesive layer 2 provided on the separator.

In the pressure-sensitive adhesive layer 2 of the dicing die-bonding film 10, the ultraviolet irradiation may be performed on a part of the pressure-sensitive adhesive layer 2 so that the adhesive strength of the part 2a becomes smaller than the adhesive strength of other parts 2b. That is, the part 2a in which the adhesive strength is decreased can be formed by using those in which the entire or a portion of the part other than the part corresponding to the semiconductor wafer pasting part 3a on at least one face of the base material 1 is shaded, forming the ultraviolet curable pressure-sensitive adhesive layer 2 onto this, then radiating ultraviolet, and curing the part corresponding the semiconductor wafer pasting part 3a. The shading material that can be a photo mask on a supporting film can be manufactured by printing, vapor deposition, etc. Accordingly, the dicing die-bonding film 10 of the present invention can be produced with efficiency.

The thickness of the pressure-sensitive adhesive layer 2 is not particularly limited. However, it is preferably about 1 to 50 μm from the viewpoint of preventing chipping of the chip cut surface, compatibility of fixing and holding of the adhesive layer, and the like. It is preferably 2 to 30 μm, and further preferably 5 to 25 μm.

The breaking energy per unit area at room temperature during expansion of the bonding part of the dicing film 11 onto a semiconductor wafer is preferably 1.5 to 2 J/mm², more preferably 1.55 to 1.95 J/mm², and further preferably 1.6 to 1.9 J/mm². The elongation at break at room temperature during expansion of the bonding part of the dicing film 11 onto a semiconductor wafer is preferably 900 to 1000%, and more preferably 910 to 990%. With the breaking energy per unit area and the elongation at break at room temperature of the dicing film 11 being within these ranges, the dicing film 11 cannot be broken in the expanding step that is described later.

The breaking energy per unit area of the die-bonding films 3 and 3′ is 1 J/mm² or less and the elongation at break of the die-bonding films 3 and 3′ is 40% or more to 500% or less at room temperature. With this configuration, the die-bonding film can be suitably broken with a tensile force. The breaking energy is preferably 0.01 J/mm² or more, and more preferably 0.05 J/mm² or more. The breaking energy is preferably 0.9 J/mm² or less, and more preferably 0.85 J/mm² or less. The elongation at break is preferably 45% or more to 480% or less, and more preferably 50% or more to 450% or less.

The tensile storage modulus of the die-bonding films 3 and 3′ at −20 to 30° C. before thermal setting is preferably 0.1 to 10 GPa, and more preferably 0.5 to 9.5 GPa. With the tensile storage modulus at −20 to 30° C. before thermal setting being 0.1 to 10 GPa, chipping can be prevented from occurring when dividing a semiconductor wafer 4 at a scheduled dividing line 4L (refer to FIG. 3) after irradiation with a laser beam. Further, positional deviation and chip scattering of a semiconductor chip 5 when the semiconductor wafer 4 is divided at the scheduled dividing line 4L can be prevented.

The lamination structure of the die-bonding film is not especially limited, and examples thereof include a single layer structure of an adhesive layer such as the die-bonding films 3 and 3′ (refer to FIGS. 1 and 2) and a multi-layered structure in which an adhesive layer is formed on one side or both sides of a core member. Examples of the core member include films (such as polyimide film, polyester film, polyethylene terephthalate film, polyethylene naphthalate film, and polycarbonate film); resin substrates which are reinforced with glass fiber or plastic nonwoven finer; silicon substrates; and glass substrates.

The adhesive composition constituting the die-bonding films 3, 3′ include those in which a thermoplastic resin is used in combination with a thermosetting resin.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

At least one of the epoxy resin and the phenol resin preferably contains one type or more of a resin having a melting point of 50° C. or more. The die-bonding film can be more suitably broken with the tensile force when a resin having the melting point of 50° C. or more is contained. Examples of the epoxy resin having a melting point of 50° C. or more include AER-8039 (manufactured by Asahi Kasei Epoxy, melting point 78° C.), BREN-105 (manufactured by Nippon Kayaku Co., Ltd., melting point 64° C.), BREN-S (manufactured by Nippon Kayaku Co., Ltd., melting point 83° C.), CER-3000L (manufactured by Nippon Kayaku Co., Ltd., melting point 90° C.), EHPE-3150 (manufactured by Daicel Chemical Industries, Ltd., melting point 80° C.), EPPN-501HY (manufactured by Nippon Kayaku Co., Ltd., melting point 60° C.), ESN-165M (manufactured by Nippon Steel Chemical Co., Ltd., melting point 76° C.), ESN-175L (manufactured by Nippon Steel Chemical Co., Ltd., melting point 90° C.), ESN-175S (manufactured by Nippon Steel Chemical Co., Ltd., melting point 67° C.), ESN-355 (manufactured by Nippon Steel Chemical Co., Ltd., melting point 55° C.), ESN-375 (manufactured by Nippon Steel Chemical Co., Ltd., melting point 75° C.), ESPD-295 (manufactured by Sumitomo Chemical Co., Ltd., melting point 69° C.), EXA-7335 (manufactured by DIC Corporation, melting point 99° C.), EXA-7337 (manufactured by DIC Corporation, melting point 70° C.), HP-7200H (manufactured by DIC Corporation, melting point 82° C.), TEPIC-SS (manufactured by Nissan Chemical Industries, Ltd., melting point 108° C.), YDC-1312 (manufactured by Tohto Kasei Co., Ltd., melting point 141° C.) YDC-1500 (manufactured by Tohto Kasei Co., Ltd., melting point 101° C.), YL-6121HN (manufactured by Japan Epoxy Resin Co., Ltd., melting point 130° C.), YSLV-120TE (manufactured by Tohto Kasei Co., Ltd., melting point 113° C.) YSLV-80XY (manufactured by Tohto Kasei Co., Ltd., melting point 80° C.), YX-4000H (manufactured by Japan Epoxy Resin Co., Ltd., melting point 105° C.) YX-4000K (manufactured by Japan Epoxy Resin Co., Ltd., melting point 107° C.), ZX-650 (manufactured by Tohto Kasei Co., Ltd., melting point 85° C.) Epicoat 1001 (manufactured by Japan Epoxy Resin Co., Ltd., melting point 64° C.), Epicoat 1002 (manufactured by Japan Epoxy Resin Co., Ltd., melting point 78° C.), Epicoat 1003 (manufactured by Japan Epoxy Resin Co., Ltd., melting point 89° C.), Epicoat 1004 (manufactured by Japan Epoxy Resin Co., Ltd., melting point 97° C.), and Epicoat 1006FS (manufactured by Japan Epoxy Resin Co., Ltd., melting point 112° C.). Among these, AER-8039 (manufactured by Asahi Kasei Epoxy, melting point 78° C.) BREN-105 (manufactured by Nippon Kayaku Co., Ltd., melting point 64° C.) BREN-S (manufactured by Nippon Kayaku Co., Ltd., melting point 83° C.), CER-3000L (manufactured by Nippon Kayaku Co., Ltd., melting point 90° C.), EHPE-3150 (manufactured by Daicel Chemical Industries, Ltd., melting point 80° C.), EPPN-501HY (manufactured by Nippon Kayaku Co., Ltd., melting point 60° C.), ESN-165M (manufactured by Nippon Steel Chemical Co., Ltd., melting point 76° C.), ESN-175L (manufactured by Nippon Steel Chemical Co., Ltd., melting point 90° C.), ESN-175S (manufactured by Nippon Steel Chemical Co., Ltd., melting point 67° C.), ESN-355 (manufactured by Nippon Steel Chemical Co., Ltd., melting point 55° C.), ESN-375 (manufactured by Nippon Steel Chemical Co., Ltd., melting point 75° C.), ESPD-295 (manufactured by Sumitomo Chemical Co., Ltd., melting point 69° C.), EXA-7335 (manufactured by DIC Corporation, melting point 99° C.), EXA-7337 (manufactured by DIC Corporation, melting point 70° C.), HP-7200H (manufactured by DIC Corporation, melting point 82° C.), YSLV-80XY (manufactured by Tohto Kasei Co., Ltd., melting point 80° C.) ZX-650 (manufactured by Tohto Kasei Co., Ltd., melting point 85° C.) Epicoat 1001 (manufactured by Japan Epoxy Resin Co., Ltd., melting point 64° C.), Epicoat 1002 (manufactured by Japan Epoxy Resin Co., Ltd., melting point 78° C.), Epicoat 1003 (manufactured by Japan Epoxy Resin Co., Ltd., melting point 89° C.), and Epicoat 1004 (manufactured by Japan Epoxy Resin Co., Ltd., melting point 97° C.) are preferable. Because the melting point of these epoxy resins is not too high (less than 100° C.) the semiconductor wafer 4 can be easily bonded onto the die-bonding films 3 and 3′ when mounting the semiconductor wafer 4 onto the die-bonding films 3 and 3′. Examples of the phenol resin having a melting point of 50° C. or more include DL-65 (manufactured by Meiwa Plastic Industries, Ltd., melting point 65° C.), DL-92 (manufactured by Meiwa Plastic Industries, Ltd., melting point 92° C.), DPP-L (manufactured by Nippon Oil Corporation, melting point 100° C.), GS-180 (manufactured by Gunei Chemical Industry Co., Ltd., melting point 83° C.), GS-200 (manufactured by Gunei Chemical Industry Co., Ltd., melting point 100° C.); H-1 (manufactured by Meiwa Plastic Industries, Ltd., melting point 79° C.), H-4 (manufactured by Meiwa Plastic Industries, Ltd., melting point 71° C.), HE-100C-15 (manufactured by Sumitomo Chemical Co., Ltd., melting point 73° C.), HE-510-05 (manufactured by Sumitomo Chemical Co., Ltd., melting point 75° C.), HF-1 (manufactured by Meiwa Plastic Industries, Ltd., melting point 84° C.), HF-3 (manufactured by Meiwa Plastic Industries, Ltd., melting point 96° C.) MEH-7500 (manufactured by Meiwa Plastic Industries, Ltd., melting point 111° C.), MEH-7500-3S (manufactured by Meiwa Plastic Industries, Ltd., melting point 83° C.), MEH-7800-3L (manufactured by Meiwa Plastic Industries, Ltd., melting point 72° C.) MEH-7851 (manufactured by Meiwa Plastic Industries, Ltd., melting point 78° C.) MEH-7851-3H (manufactured by Meiwa Plastic Industries, Ltd., melting point 105° C.), MEH-7851-4H (manufactured by Meiwa Plastic Industries, Ltd., melting point 130° C.), MEH-7851S (manufactured by Meiwa Plastic Industries, Ltd., melting point 73° C.), P-1000 (manufactured by Arakawa Chemical Industries, Ltd., melting point 63° C.), P-180 (manufactured by Arakawa Chemical Industries, Ltd., melting point 83° C.), P-200 (manufactured by Arakawa Chemical Industries, Ltd., melting point 100° C.), VR-8210 (manufactured by Mitsui Chemicals, Inc., melting point 60° C.), XLC-3L (manufactured by Mitsui Chemicals, Inc., melting point 70° C.) XLC-4L (manufactured by Mitsui Chemicals, Inc., melting point 62° C.), and XLC-LL (manufactured by Mitsui Chemicals, Inc., melting point 75° C.). Among these, DL-65 (manufactured by Meiwa Plastic Industries, Ltd., melting point 65° C.), DL-92 (manufactured by Meiwa Plastic Industries, Ltd., melting point 92° C.), GS-180 (manufactured by Gunei Chemical Industry Co., Ltd., melting point 83° C.), H-1 (manufactured by Meiwa Plastic Industries, Ltd., melting point 79° C.), H-4 (manufactured by Meiwa Plastic Industries, Ltd., melting point 71° C.), HE-100C-15 (manufactured by Sumitomo Chemical Co., Ltd., melting point 73° C.), HE-510-05 (manufactured by Sumitomo Chemical Co., Ltd., melting point 75° C.), HF-1 (manufactured by Meiwa Plastic Industries, Ltd., melting point 84° C.), HF-3 (manufactured by Meiwa Plastic Industries, Ltd., melting point 96° C.), MEH-7500-3S (manufactured by Meiwa Plastic Industries, Ltd., melting point 83° C.), MEH-7800-3L (manufactured by Meiwa Plastic Industries, Ltd., melting point 72° C.), MEH-7851 (manufactured by Meiwa Plastic Industries, Ltd., melting point 78° C.), MEH-7851S (manufactured by Meiwa Plastic Industries, Ltd., melting point 73° C.), P-1000 (manufactured by Arakawa Chemical Industries, Ltd., melting point 63° C.), P-180 (manufactured by Arakawa Chemical Industries, Ltd., melting point 83° C.), VR-8210 (manufactured by Mitsui Chemicals, Inc., melting point 60° C.), XLC-3L (manufactured by Mitsui Chemicals, Inc., melting point 70° C.), XLC-4L (manufactured by Mitsui Chemicals, Inc., melting point 62° C.), and XLC-LL (manufactured by Mitsui Chemicals, Inc., melting point 75° C.) are preferable. Because the melting point of these phenol resins is not too high (less than 100° C.), the semiconductor wafer 4 can be easily bonded onto the die-bonding films 3 and 3′ when mounting the semiconductor wafer 4 onto the die-bonding films 3 and 3′.

Examples of the thermoplastic resin include a natural rubber, a butyl rubber, an isoprene rubber, a chloroprene rubber, and ethylene-vinyl acetate copolymer, an ethylene-acrylic acid copolymer, an ethylene-acrylic ester copolymer, a polybutadiene resin, a polycarbonate resin, a thermoplastic polyimide resin, a polyamide resin such as 6-nylon or 6,6-nylon, a phenoxy resin, an acrylic resin, a saturated polyester resin such as PET or PBT, a polyamideimide resin, and a fluororesin. These thermoplastic resins can be used alone or two types or more can be used together. Among these thermoplastic resins, an acrylic resin is especially preferable because it has a small amount of ionic impurities, high heat resistance, and can secure reliability of a semiconductor element.

The acrylic resin is not especially limited, and examples thereof include a polymer (an acrylic copolymer) that is constituted from one type or two types or more of acrylic acid ester or methacrylic acid esters having linear or branched alkyl groups having 30 or leas carbon atoms, especially 4 to 18 carbon atoms. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group. Among the acrylic resins, an acrylic copolymer is especially preferable due to improvement in cohesive strength. Examples of the acrylic copolymer include a copolymer of ethyl acrylate and methyl methacrylate, a copolymer of acrylic acid and acrylonitrile, and a copolymer of butyl acrylate and acrylonitrile.

Other monomers that form the polymer are not especially limited, and examples thereof include carboxyl group-containing monomers such as acrylic acid, methacrylic acid, carboxyethyl acrylate, carboxypentyl acrylate, itaconic acid, maleic acid, fumaric acid, and crotonic acid, acid anhydride monomers such as maleic anhydride and itaconic anhydride, hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)-methylacrylate, sulfonic acid group-containing monomers such as styrene sulfonate, allyl sulfonate, 2-(meth)acrylamide-2-methylpropane sulfonic acid, (meth)acrylamidepropane sulfonic acid, sulfopropyl(meth)acrylate, and (meth)acryloyloxynaphthalene sulfonic acid, and phosphate group-containing monomers such as 2-hydroyethylacryloyl phosphate.

The mixing ratio of the thermosetting resin is not especially limited as long as it is a ratio at which a thermosetting function of the die-bonding films 3 and 3′ can be exhibited when the films are heated under predetermined conditions. However, it is preferably 5 to 60% by weight and more preferably 10 to 50% by weight.

Among the die-bonding films 3 and 3′, die-bonding films are preferable in which the adhesive layer contains an epoxy resin and a phenol resin as thermosetting resins and also contains an acrylic resin as a thermoplastic resin and when the total weight of the epoxy resin and the phenol resin is regarded as X and the weight of the acrylic resin is regarded as Y, the value of X/(X+Y) is preferably 0.3 or more and less than 0.9, more preferably 0.35 or more and less than 0.85, and further preferably 0.4 or more and less than 0.8. By making the value of X/(X+Y) be 0.3 or more and less than 0.9, the processability can be secured and the breakage can easily occur.

In order to crosslink the die-bonding film 3, 3′ of the present invention to some extent in advance, it is preferable to add, as a crosslinking agent, a polyfunctional compound which reacts with functional groups of molecular chain terminals of the above-mentioned polymer to the materials used when the sheet 12 is produced. In this way, the adhesive property of the sheet at high temperatures is improved so as to improve the heat resistance.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

A filler can be appropriately mixed into the die-bonding films 3, 3′ according to their use. By mixing the filler, electroconductivity can be given, thermal conductivity can be improved, and the elastic modulus can be adjusted. Examples of the filler include an inorganic filler and an organic filler. However, an inorganic filler is preferable from the viewpoint of improving handling property, improving thermal conductivity, adjusting melt viscosity, and giving thixotropy. The inorganic filler is not especially limited, and examples thereof include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, crystalline silica, and amorphous silica. These can be used alone or two types or more can be used together. From the viewpoint of improving thermal conductivity, aluminum oxide, aluminum nitride, boron nitride, crystalline silica, and amorphous silica are preferable. From the viewpoint of obtaining a good balance among the above-described characteristics, crystalline silica and amorphous silica are preferable. Further, an electroconductive substance (electroconductive filler) may be used as the inorganic filler for the purpose of giving electroconductivity and improving the thermal conductivity. Examples of the electroconductive filler include spherical-shaped, needle-shaped, or flake-shaped metal powders of silver, aluminum, gold, copper, nickel, and electroconductive alloys, metal oxides such as alumina, amorphous carbon black, and graphite.

The average particle size of the filler is preferably 0.005 to 10 μm, and more preferably 0.005 to 1 μm. With the average particle size of the filler being 0.005 μm or more, the wettability and the tackiness to the adherend can be improved. With the particle size being 10 μm or less, the effect of the filler added to give the above-described characteristics can be made sufficient, and heat resistance can be secured. The value of the average particle size of the filler is obtained with a luminous intensity type particle size distribution meter (manufactured by HORIBA, Ltd., device name: LA-910), for example.

The adhesive layer contains an epoxy resin and a phenol resin as thermosetting resins, an acrylic resin as a thermoplastic resin, and a filler. When the total weight of the epoxy resin, the phenol resin, and the acrylic resin is regarded as A and the weight of the filler is regarded as B, the value of A/(A+B) is preferably 0.1 or more to 0.7 or less, more preferably 0.1 or more to 0.65 or less, and further preferably 0.1 of more to 0.6 or less. With this value being 0.7 or less, the tensile storage modulus is prevented from becoming large, and wettability and tackiness to the adherend can be improved. With this value being 0.1 or more, the die-bonding film can be suitably broken with a tensile force.

Moreover, other additives besides the filler can be appropriately mixed into the die-bonding films 3 and 3′ as necessary. Examples thereof include a flame retardant, a silane coupling agent, and an ion trapping agent. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These may be used alone or in combination of two or more thereof.

The thickness of the die-bonding films 3 and 3′ (the total thickness in the case of a laminated body) is not especially limited. However, it can be selected from a range of 1 to 200 μm, for example. It is preferably selected from a range of 5 to 100 μm, and more preferably 10 to 80 μm.

The die-bonding films 3, 3′ of the dicing die-bonding films 10, 11 are preferably protected by a separator (not shown). The separator has a function as a protecting material that protects the die-bonding films 3, 3′ until they are practically used. Further, the separator can be used as a supporting base material when transferring the die-bonding films 3, 3′ to the pressure-sensitive adhesive layer 2. The separator is peeled when pasting a workpiece onto the die-bonding films 3, 3′ of the dicing die-bonding film. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator.

The dicing die-bonding films 10, 11 according to the present embodiment are produced, for example, by the following procedure.

First, the base material 1 can be formed by a conventionally known film-forming method. The film-forming method includes, for example, a calendar film-forming method, a casting method in an organic solvent, an inflation extrusion method in a closed system, a T-die extrusion method, a co-extrusion method, and a dry lamination method.

Next, a pressure-sensitive adhesive composition solution is applied on the base material 1 to form a coated film and the coated film is dried under predetermined conditions (optionally crosslinked with heating) to form the pressure-sensitive adhesive layer 2. Examples of the application method include, but are not limited to, roll coating, screen coating and gravure coating methods. Drying is conducted under the drying conditions, for example, the drying temperature within a range from 80 to 150° C. and the drying time within a range from 0.5 to 5 minutes. The pressure-sensitive adhesive layer 2 may also be formed by applying a pressure-sensitive adhesive composition on a separator to form a coated film and drying the coated film under the drying conditions. Then, the pressure-sensitive adhesive layer 2 is laminated on the base material 1 together with the separator. Thus, the dicing film 11 is produced.

The die-bonding films 3, 3′ are produced, for example, by the following procedure.

First, an adhesive composition solution as a material for forming the dicing die-bonding films 3, 3′ is produced. As described above, the adhesive composition solution is blended with the adhesive composition, a filler, and various additives.

Next, the adhesive composition solution is applied on a substrate separator to form a coated film having a predetermined thickness and the coated film is dried under predetermined conditions to form an adhesive layer. Examples of the application method include, but are not limited to, roll coating, screen coating and gravure coating methods. Drying is conducted under the drying conditions, for example, the drying temperature within a range from 70 to 160° C. and the drying time within a range from 1 to 5 minutes. An adhesive layer may also be formed by applying a pressure-sensitive adhesive composition solution on a separator to form a coated film and drying the coated film under the drying conditions. On the substrate separator, the adhesive layer is layered together with a separator.

Subsequently, each separator is peeled from the dicing film 11 and the adhesive layer and both are laminated to each other so that the adhesive layer and the pressure-sensitive adhesive layer serve as a laminating surface. Lamination is conducted, for example, by contact bonding. At this time, the lamination temperature is not particularly limited and is, for example, preferably from 30 to 50° C., and more preferably from 35 to 45° C. The linear pressure is not particularly limited and is, for example, from 0.1 to 20 kgf/cm, and more preferably from 1 to 10 kgf/cm. Then, the substrate separator on the adhesive layer is peeled to obtain the dicing die-bonding film according to the present embodiment.

(Method of Manufacturing Semiconductor Device)

Next, a method of manufacturing a semiconductor device using the dicing die-bonding film 12 is explained by referring to FIGS. 3 to 8. The method of manufacturing a semiconductor device according to the present embodiment includes a pretreatment step of pretreating the semiconductor wafer 4 so that it can be easily divided at the scheduled dividing lines 4L later, a mounting step of bonding the semiconductor wafer 4 after the pretreatment onto the dicing die-bonding film 12, an expanding step of forming the semiconductor chips 5 by breaking the semiconductor wafer 4 and the die-bonding film 3′ that constitutes the dicing die-bonding film 12 at the scheduled dividing lines 4L by applying a tensile force to the dicing die-bonding film 12, a pickup step of picking up the semiconductor chips 5 that are adhered and fixed to the dicing die-bonding film 12, a temporary fixing step of die-bonding the semiconductor chips 5 that are picked up onto the adherend 6 through the die-bonding film 3′, a wire bonding step of performing wire bonding to the semiconductor chips 5 after the temporary fixing step, and a sealing step of sealing the semiconductor chips 5 that are wire-bonded in the wire bonding step with a sealing resin 8.

FIGS. 3 to 6 are schematic sectional views for explaining one method of manufacturing a semiconductor device according to the present embodiment. First, a pretreatment is carried out on the semiconductor wafer 4 that enables the wafer to be easily divided at the scheduled dividing lines 4L later (the pretreatment step). An example of this step is a method of forming a reformed region on the scheduled dividing lines 4L by irradiating the semiconductor wafer with a laser beam as shown in FIG. 3. The present method is a method of forming a reformed region inside the semiconductor wafer by ablation caused by multi-photon absorption by focusing condensing points on the inside of the semiconductor wafer and irradiating the semiconductor water with a laser beam along the lattice-shaped scheduled dividing lines. The irradiation conditions of the laser beam are appropriately adjusted within the following ranges.

<Laser Beam Irradiation Conditions>

(A) Laser Beam

Laser Beam Source Semiconductor laser excitation Nd:YAG laser

Wavelength 1064 nm

Sectional Area of Laser Spot 3.14×10⁻⁸ cm²

Laser Oscillation Form Q switch pulse

Repetition Frequency 100 kHz or less

Pulse Width 1 μs or less

Output 1 mJ or less

Quality of Laser Beam TEM00

Polarization Characteristic Linear polarization

(B) Beam Collecting Lens

Magnification 100 times or less

NA 0.55

Transmittance to Laser Beam Wavelength 100% or less

(C) Movement Speed of the Stage on Which Semiconductor Substrate is Loaded 280 mm/sec or Less

A detailed explanation of the method of forming a reformed region on the scheduled dividing lines 4L by irradiating the semiconductor wafer with a laser beam is omitted because it is specifically described in Japanese Patent No. 3408805 and Japanese Patent Application Laid-Open No. 2003-338567.

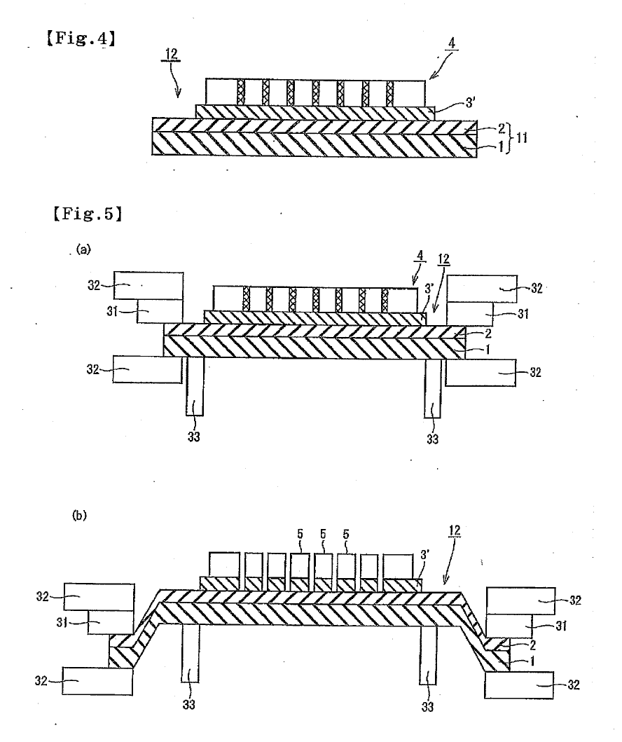

Next, the pretreated semiconductor wafer 4 is fixed onto the die-bonding film 3′ by press-bonding and holding the adhesion (the mounting step) as shown in FIG. 4. This step is performed while pressing the wafer with a pressing means such as a press bonding roll. The bonding temperature during mounting is not especially limited, however, it is preferably in the range of 40 to 80° C. This is because warping of the semiconductor wafer 4 can be effectively prevented and the influence of expansion and contraction of the dicing die-bonding film can be reduced.

Next, the semiconductor chip 5 is formed by applying a tensile force to the dicing die-bonding film 12 and breaking the semiconductor wafer 4 and the die-bonding film 3′ (the expanding step). In this step, a wafer expander on the market can be used, for example. Specifically, a dicing ring 31 is bonded onto the peripheral part of a pressure-sensitive adhesive layer 2 of the dicing die-bonding film 12 on which the semiconductor wafer 4 is bonded, and then it is fixed onto a wafer expander 32 as shown in FIG. 5A. Next, a tensile force is applied to the dicing die-bonding film 12 by raising a push-up part 33 as shown in FIG. 5B.

The expansion speed (the rising speed of the push-up part) is preferably 1 to 400 mm/sec, and more preferably 50 to 400 mm/sec. With the expansion speed being 1 mm/sec or more, the semiconductor wafer 4 and the die-bonding film 3′ can be nearly simultaneously and easily broken. With the expansion speed being 400 mm/sec or less, the dicing film 11 can be prevented from being broken.

The expansion amount (the amount of raise of the push-up part) is preferably 5 to 50 mm, more preferably 5 to 40 mm, and especially preferably 5 to 30 mm. With the expansion amount being 5 mm or more, breakage of the semiconductor wafer 4 and the die-bonding film 3 can be made easy. With the expansion amount being 50 mm or less, the dicing film 11 can be prevented from being broken.

The expansion temperature may be adjusted within −50 to 100° C. as necessary. However, it is preferably −20 to 30° C. and more preferably −10 to 25° C. in the present invention. A lower expansion temperature is preferable in respect of preventing the lowering of the yield due to insufficient breakage of the die-bonding film, because when the temperature is low, the breaking expansion is small and the die-bonding film can be easily broken.

As described above, cracks can be generated in the thickness direction of the semiconductor wafer 4 with the reformed region of the semiconductor wafer 4 as a starting point, the die-bonding film 3′ that is closely attached to the semiconductor wafer 4 can be broken by applying a tensile force to the dicing die-bonding film 12, and the semiconductor chip 5 with the die-bonding film 3′ can be obtained.

Next, pickup of the semiconductor chip 5 is performed to peel off the semiconductor chip 5 that is adhered and fixed onto the dicing die-bonding film 12 (the pickup step). The method of picking up is not particularly limited, and conventionally known various methods can be adopted. Examples include a method of pushing up the individual semiconductor chip 5 from the dicing die-bonding 10 side with a needle and picking up the pushed semiconductor chip 5 with a picking-up apparatus.

Here, the picking up is performed after radiating the pressure-sensitive adhesive layer 2 with ultraviolet rays because the pressure-sensitive adhesive layer 2 is an ultraviolet curable type pressure-sensitive adhesive layer. Accordingly, the adhesive strength of the pressure-sensitive adhesive layer 2 to the die-bonding film 3a decreases, and the peeling of the semiconductor chip 5 becomes easy. As a result, picking up becomes possible without damaging the semiconductor chip 5. The condition such as irradiation intensity and irradiation time when irradiating an ultraviolet ray is not particularly limited, and it may be appropriately set depending on necessity. Further, the light source as described above can be used as a light source used in the ultraviolet irradiation.

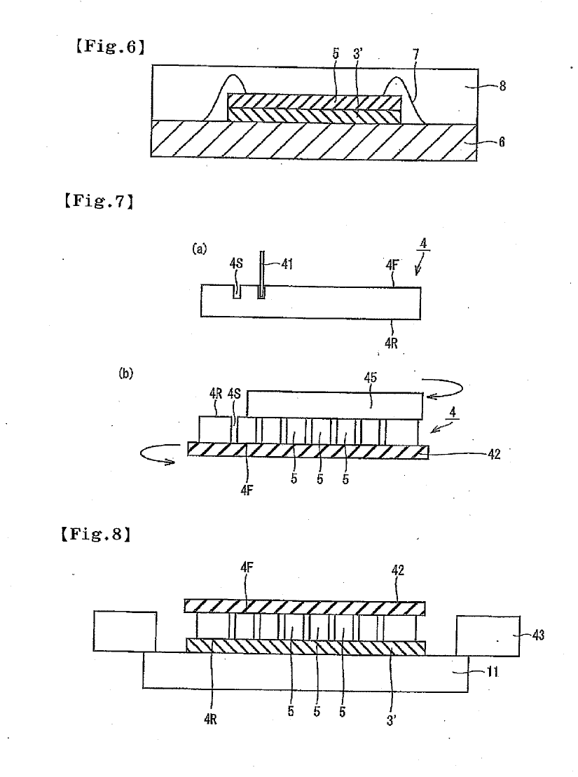

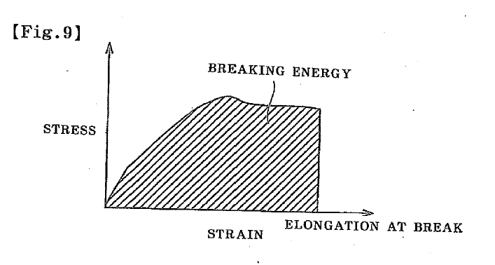

Next, the semiconductor chip 5 that is picked up is die-bonded to the adherend 6 through the die-bonding film 3′ as shown in FIG. 6 (the temporary fixing step). Examples of the adherend 6 include such as a lead frame, a TAB film, a substrate, and a semiconductor chip separately produced. The adherend 6 may be a deformable adherend that are easily deformed, or may be a non-deformable adherend (a semiconductor wafer, etc.) that is difficult to deform, for example.

A conventionally known substrate can be used as the substrate. Further, a metal lead frame such as a Cu lead frame and a 42 Alloy lead frame and an organic substrate composed of glass epoxy, BT (bismaleimide-triazine), and polyimide can be used as the lead frame. However, the present invention is not limited to this, and includes a circuit substrate that can be used by mounting a semiconductor element and electrically connecting with the semiconductor element.

The shear adhering strength to the adherend 6 at 25° C. during the temporary fixing of the die-bonding film 3′ is preferably 0.2 MPa or more, and more preferably 0.2 to 10 MPa. When the shear adhering strength of the die-bonding film 3 is at least 0.2 MPa, shear deformation rarely occurs at the adhering surface between the die-bonding film 3 and the semiconductor chip 5 or the adherend 6 during the wire bonding step due to ultrasonic vibration and heating in this step. That is, the semiconductor element rarely moves due to the ultrasonic vibration during the wire bonding, and with this, the success rate of the wire bonding can be prevented from decreasing. The shear adhering strength to the adherend 6 at 175° C. during the temporary fixing of the die-bonding film 3′ is preferably 0.01 MPa or more, and more preferably 0.01 to 5 MPa.

Next, wire bonding is performed to electrically connect a tip of a terminal part (inner lead) of the adherend 6 and an electrode pad (not shown) on the semiconductor chip 5 with a bonding wire 7 (the wire bonding step). The bonding wires 7 may be, for example, gold wires, aluminum wires, or copper wires. The temperature when the wire bonding is performed is from 80 to 250° C., preferably from 80 to 220° C. The heating time is from several seconds to several minutes. The connection of the wires is performed by using a combination of vibration energy based on ultrasonic waves with compression energy based on the application of pressure in the state that the wires are heated to a temperature in the above-mentioned range. The present step can be conducted without thermal setting of the die-bonding film 3a. In the process of the step, the semiconductor chip 5 and the adherend 6 are not fixed to each other by the die-bonding film 3a.

Next, the semiconductor chip 5 is sealed with the sealing resin 8 (the sealing step). The present step is performed by molding the sealing resin with a mold or die. The sealing resin 8 may be, for example, an epoxy resin. The heating for the resin-sealing is performed usually at 175° C. for 60 to 90 seconds. In the this invention, however, the heating is not limited to this, and may be performed, for example at 165 to 185° C. for several minutes. In such a way, the sealing resin is cured and further the semiconductor chip 5 and the adherend 6 are set to each other through the adhesive sheet 3a. In short, even if the below mentioned post-curing step, which will be detailed later, is not performed in this invention, the sticking/fixing based on the adhesive sheet 3a can be attained in the present step so that the number of the producing steps can be reduced and the term for producing the semiconductor device can be shortened.

In the post-curing step, the sealing resin 8, which is not sufficiently cured in the sealing step, is completely cured. Even if the die-bonding film 3a is not completely cured in the step of sealing, the die-bonding film 3a and sealing resin 8 can be completely cured in the present step. The heating temperature in the present step is varied dependently on the kind of the sealing resin, and is, for example, in the range of 165 to 185° C. The heating time is from about 0.5 to 8 hours.

The case of temporarily fixing the semiconductor chip 5 with the die-bonding film 3′ to the adherend 6 and then performing the wire bonding step without completely thermally curing the die-bonding film 3′ is explained in the above-described embodiment. However, a normal die bonding step of temporarily fixing the semiconductor chip 5 with the die-bonding film 3′ to the adherend 6, thermally curing the die-bonding film 3′, and then performing the wire bonding step may be performed in the present invention. In this case, the die-bonding film 3′ after the thermal setting preferably has a shear adhering strength at 175° C. of 0.01 MPa or more, and more preferably 0.01 to 5 MPa. With the shear adhering strength at 175° C. after the thermal setting being 0.01 MPa or more, the shear deformation at the adhering surface between the die-bonding film 3′ and the semiconductor chip 5 or the adherend 6 due to ultrasonic vibration and heating during the wire bonding step can be prevented from occurring.

The dicing die-bonding film of the present invention can be suitably used when laminating a plurality of semiconductor chips to carry out three-dimensional mounting. At this time, a die-bonding film and a spacer may be laminated between the semiconductor chips, or only a die-bonding film may be laminated between semiconductor chips without laminating a spacer. The mode of mounting can be appropriately changed according to the manufacturing condition and the use.

In the above-described embodiment, a method of forming a reformed region on the scheduled dividing lines 4L by irradiating a wafer with a laser beam as the pretreatment step is explained. However, grooves may be formed on the surface of a semiconductor wafer as the pretreatment step, and then a step of performing backside grinding may be adopted in the present invention. A method of manufacturing a semiconductor device in this case is explained in the following.

FIGS. 7 and 8 are schematic sectional views for explaining another method of manufacturing a semiconductor device according to the present embodiment. First, a groove 4S that does not reach backside 4R is formed on a surface 4F of the semiconductor wafer 4 with a rotary blade 41 as shown in FIG. 7A. The semiconductor wafer 4 is supported by a supporting base (for example, a dicing film) that is not shown during the formation of the groove 4S. The depth of the groove 4S can be appropriately set depending on the thickness of the semiconductor wafer 4 and the expansion condition. Next, the semiconductor wafer 4 is made to be supported by a protecting base 42 so that the surface 4F is brought into contact with itself as shown in FIG. 7B. Then, the groove 4S is exposed from the backside 4R by performing backside grinding with a grinding wheel 45. By this operation, the semiconductor chip 5 is formed. A conventionally known bonding apparatus can be used to bond the protecting base 42 onto the semiconductor wafer, and a conventionally known grinding apparatus can be used for the backside grinding. The above description is explanation of the pretreatment step.

Next, the pretreated semiconductor chip 5 is fixed onto the die-bonding film 3′ by press-bonding and the adhesion is held (the temporary fixing step) as shown in FIG. 8. Then, the protecting base 42 is peeled off, and the expanding step is performed. This expanding step may be the same as in the case of forming the reformed region on the scheduled dividing lines 4L by irradiating the semiconductor wafer with a laser beam. Explanation of the following processes is omitted because it is the same as the case where the reformed region is formed on the scheduled dividing lines 4L by irradiating the semiconductor wafer with a laser beam.

Below, preferred examples of the present invention are explained in detail. However, materials, addition amounts, and the like described in these examples are not intended to limit the scope of the present invention, and are only examples for explanation as long as there is no description of limitation in particular.

### Example 1

A solution of an adhesive composition having a concentration of 23.6% by weight was obtained by dissolving the following (a) to (d) in methyl ethyl ketone.

(a) Epoxy resin (manufactured by Japan Epoxy Resin Co., Ltd., Epicoat 1004, melting point 97° C.) 113 parts by weight

(b) Phenol resin (manufactured by Mitsui Chemicals, Inc., Milex XLC-4L, melting point 59° C.) 121 parts by weight

(c) Acrylic ester polymer having ethyl acrylate-methyl methacrylate as a main component (manufactured by Nagase ChemteX Corporation, WS-023) 100 parts by weight

(d) Spherical silica (manufactured by Admatechs Co., Ltd., SO-25R) 37 parts by weight

This adhesive composition solution was applied on a release-treated film (peel liner) composed of a 50 μm thick polyethylene terephthalate film subjected to a silicone release treatment and then dried at 130° C. for 2 minutes to produce a 25 μm thick die-bonding film A.

### Example 2

In Example 2, a die-bonding film B according to the present example was produced in the same manner as in Example 1 except that the amount of addition of the spherical silica of (d) was changed to 222 parts by weight.

### Example 3

In Example 3, a die-bonding film C according to the present example was produced in the same manner as in Example 1 except that the amount of addition of the spherical silica of (d) was changed to 779 parts by weight.

### Example 4

A solution of an adhesive composition having a concentration of 23.6% by weight was obtained by dissolving the following (a) to (d) in methyl ethyl ketone.

(a) Epoxy resin (manufactured by Japan Epoxy Resin Co., Ltd., Epicoat 1001, melting point 64° C.) 32 parts by weight

(b) Phenol resin (manufactured by Mitsui Chemicals, Inc., Milex XLC-4L, melting point 59° C.) 34 parts by weight

(c) Acrylic ester polymer having ethyl acrylate-methyl methacrylate as a main component (manufactured by Nagase ChemteX Corporation, WS-023) 100 parts by weight

(d) Spherical silica (manufactured by Admatechs Co., Ltd., SO-25R) 18 parts by weight

This adhesive composition solution was applied on a release-treated film (peel liner) composed of a 50 μm thick polyethylene terephthalate film subjected to a silicone release treatment and then dried at 130° C. for 2 minutes to produce a 25 μm thick die-bonding film D.

### Example 5

A solution of an adhesive composition having a concentration of 23.6% by weight was obtained by dissolving the following (a) to (d) in methyl ethyl ketone.

(a) Epoxy resin (manufactured by Japan Epoxy Resin Co., Ltd., Epicoat 1001, melting point 64° C.) 32 parts by weight

(b) Phenol resin (manufactured by Mitsui Chemicals, Inc., MEH 7851, melting point 64° C.) 34 parts by weight

(c) Acrylic ester polymer having ethyl acrylate-methyl methacrylate as a main component (manufactured by Nagase ChemteX Corporation, WS-023) 100 parts by weight

(d) Spherical silica (manufactured by Admatechs Co., Ltd., SO-25R) 100 parts by weight

This adhesive composition solution was applied on a release-treated film (peel liner) composed of a 50 μm thick polyethylene terephthalate film subjected to a silicone release treatment and then dried at 130° C. for 2 minutes to produce a 25 μm thick die-bonding film E.

### Example 6

In Example 6, a die-bonding film F according to the present example was produced in the same manner as in Example 4 except that the amount of addition of the spherical silica of (d) was changed to 387 parts by weight.

### Comparative Example 1

A solution of an adhesive composition having a concentration of 23.6% by weight was obtained by dissolving the following (a) to (d) in methyl ethyl ketone.

(a) Epoxy resin (manufactured by Japan Epoxy Resin Co., Ltd., Epicoat 1004, melting point 97° C.) 11 parts by weight

(b) Phenol resin (manufactured by Mitsui Chemicals, Inc., Milex XLC-4L, melting point 59° C.) 13 parts by weight

(c) Acrylic ester polymer having ethyl acrylate-methyl methacrylate as a main component (manufactured by Nagase ChemteX Corporation, WS-023) 100 parts by weight

(d) Spherical silica (manufactured by Admatechs Co., Ltd., SO-25R) 1287 parts by weight

This adhesive composition solution was applied on a release-treated film (peel liner) composed of a 50 μm thick polyethylene terephthalate film subjected to a silicone release treatment and then dried at 130° C. for 2 minutes to produce a 25 μm thick die-bonding film G.

### Comparative Example 2

A solution of an adhesive composition having a concentration of 23.6% by weight was obtained by dissolving the following (a) to (d) in methyl ethyl ketone.

(a) Epoxy resin (manufactured by Japan Epoxy Resin Co., Ltd., Epicoat 827, liquid at room temperature) 917 parts by weight

(b) Phenol resin (manufactured by Mitsui Chemicals, Inc., Milex XLC-4L, melting point 59° C.) 983 parts by weight

(c) Acrylic ester polymer having ethyl acrylate-methyl methacrylate as a main component (manufactured by Nagase ChemteX Corporation, WS-023) 100 parts by weight

(d) Spherical silica (manufactured by Admatechs Co., Ltd., SO-25R) 1333 parts by weight

This adhesive composition solution was applied on a release-treated film (peel liner) composed of a 50 μm thick polyethylene terephthalate film subjected to a silicone release treatment and then dried at 130° C. for 2 minutes to produce a 25 μm thick die-bonding film H.

### Comparative Example 3

A solution of an, adhesive composition having a concentration of 23.6% by weight was obtained by dissolving the following (a) to (d) in methyl ethyl ketone.

(a) Epoxy resin (manufactured by Japan Epoxy Resin Co., Ltd., Epicoat 827, liquid at room temperature) 11 parts by weight

(b) Phenol resin (manufactured by Mitsui Chemicals, Inc., Milex XLC-4L, melting point 59° C.) 13 parts by weight

(c) Acrylic ester polymer having ethyl acrylate-methyl methacrylate as a main component (manufactured by Nagase ChemteX Corporation, WS-023) 100 parts by weight

(d) Spherical silica (manufactured by Admatechs Co., Ltd., SO-25R) 7 parts by weight

This adhesive composition solution was applied on a release-treated film (peel liner) composed of a 50 μm thick polyethylene terephthalate film subjected to a silicone release treatment and then dried at 130° C. for 2 minutes to produce a 25 μm thick die-bonding film I.

### (Breaking Energy and Elongation at Break)

A rectangular measurement sample 30 mm long, 25 μm thick, and 10 mm wide was cut from each of the die-bonding films A to I. Next, a stress-strain curve was obtained under conditions of a tensile speed of 0.5 mm/min and a distance between chucks of 20 mm using a tensile test apparatus (TENSILON manufactured by Shimadzu Corporation), and a breaking energy (J) at 25° C. was obtained from the area under the stress-strain curve. The breaking energy per unit area and the elongation at break were obtained from the following formulas.

(Breaking energy per unit area (J/mm²))=(Breaking energy (J))/(0.25 (mm²))

Elongation at break (%)=(((Distance between chucks at break (mm))−20)/20)×100

(Measurement of Tensile Storage Modulus at −20 to 30° C.)

A rectangular measurement sample 40 mm long, 200 μm thick, and 10 mm wide was cut from each of the die-bonding films A to I. Next, the tensile storage modulus at −50 to 300° C. was measured under conditions of a distance between chucks of 22.5 mm, a frequency of 1 Hz, and a temperature rise rate of 10° C./min using a fixed viscoelasticity measurement apparatus (RSA III manufactured by Rheometric Scientific FE, Ltd.). The measured values at −20 to 30° C. are shown in Table 1.

(Confirmation of Bonding Property)

Dicing die-bonding films A to I were made by bonding a dicing film onto each of the die-bonding films A to I. The dicing film used included a pressure-sensitive adhesive layer (composition: acrylic polymer, film thickness: 10 μm) laminated on a base (composition: polyolefin, film thickness: 100 μm). The breaking energy and the elongation at break were measured at the bonding part of this dicing film to the semiconductor wafer to find that the breaking energy per unit area was 1.75 J/mm² and the elongation at break was 947% at room temperature. Next, the semiconductor wafer was bonded onto each of the dicing die-bonding films A to I. The case in which the semiconductor wafer did not shift from the dicing die-bonding film when it was pressed with a finger is regarded as good, and the case in which the semiconductor wafer shifted is regarded as poor.

(Confirmation of Breakage)

<Case in which a step (step 1) was adopted in which a reformed region was formed on the scheduled dividing lines 4L by irradiating the semiconductor wafer with a laser beam as the pretreatment step>

A reformed region was formed in the interior of the semiconductor wafer by focusing condensing points in the interior of the semiconductor wafer and irradiating the semiconductor wafer with a laser beam at the surface of the semiconductor wafer along the lattice-shaped (10 mm×10 mm) scheduled dividing lines using ML300-Integration manufactured by Tokyo Seimitsu Co., Ltd. as a laser beam machining apparatus. A silicon wafer (thickness: 75 μm, outer diameter: 12 inches) was used as the semiconductor wafer. The irradiation conditions of the laser beam were as follows.

<Laser Beam Irradiation Conditions>

(A) Laser Beam

Laser Beam Source Semiconductor laser excitation Nd:YAG laser

Wavelength 1064 nm

Sectional Area of Laser Spot 3.14×10⁻⁸ cm²

Laser Oscillation Form Q switch pulse

Repetition Frequency 100 kHz

Pulse Width 30 ns

Output 20 μJ/pulse

Quality of Laser Beam TEM00 40

Polarization Characteristic Linear polarization

(B) Beam Collecting Lens

Magnification 50 times

NA 0.55

Transmittance to Laser Beam Wavelength 60%

(C) Movement Speed of the Stage on Which Semiconductor Substrate is Loaded 100 mm/sec

A breaking test was performed on each of the die-bonding films A to I after bonding the semiconductor wafer on which the pretreatment by a laser beam was performed. The conditions of expansion in the breaking test were room temperature (25° C.), an expansion speed of 300 mm/sec., and an expansion amount of 30 mm. As a result of the breaking test, the case in which there was no occurrence of insufficient breakage is regarded as good, and the case in which there were places of insufficient breakage is regarded as poor.

<Case in which a step (step 2) was adopted in which grooves were formed on the surface of the semiconductor wafer and then backside grinding was performed as the pretreatment step>

Lattice-shaped (10 mm×10 mm) cut grooves were formed on the semiconductor wafer (thickness 500 μm) by blade dicing. The depth of the cut grooves was 100 μm.

Next, divided individual semiconductor chips (10 mm×10 mm×75 μm) were obtained by protecting the surface of the semiconductor wafer with a protecting tape and performing backside grinding until the thickness reached 75 μm. This semiconductor chip was bonded onto each of the die-bonding films A to I, and then the breaking test was performed. The conditions of expansion in the breaking test were room temperature (25° C.), an expansion speed of 300 mm/sec, and an expansion amount of 30 mm. As a result of the breaking test, the case in which there was no occurrence of insufficient breakage is regarded as good, and the case in which there were places of insufficient breakage is regarded as poor, similarly to the case of step 1.

(Result)

As can be understood from the result in Table 1, the bonding property and breaking property are confirmed to be good with the die-bonding films A to F having a breaking energy of 1 J/mm² or less and an elongation at break of 40% or more to 500% or less as in Examples 1 to 6.

Contrary to this, it was found that when the breaking energy exceeded 1 J/mm² and the elongation at break was less than 40% as in Comparative Example 1, the die-bonding film did not bond to the semiconductor chip and the breaking property was poor. Further, it was found that when the breaking energy exceeded 1 J/mm² and the elongation at break exceeded 500% as in Comparative Example 3, the breaking property was poor although the bonding property was good. Further, it was found that when the elongation at break was much lower than 40% as in Comparative Example 2, the breaking property was poor because the workability was poor and the die-bonding film cracked.

TABLE 1

| | | | TENSILE | | BREAKING | |
|---|---|---|---|---|---|---|
| | BREAKING | ELONGATION | STORAGE | | PROPERTY | |
| | ENERGY | AT BREAK | MODULUS | BONDING | PROCESS | PROCESS |
| | (J/mm²) | (%) | (Pa) | PROPERTY | 1 | 2 |
| Example | 0.36 | 132 | 2.34 × 10⁹ | GOOD | GOOD | GOOD |
| 1 | | | | | | |
| Example | 0.18 | 101 | 3.78 × 10⁹ | GOOD | GOOD | GOOD |
| 2 | | | | | | |
| Example | 0.08 | 48 | 8.51 × 10⁹ | GOOD | GOOD | GOOD |
| 3 | | | | | | |
| Example | 0.67 | 496 | 2.96 × 10⁸ | GOOD | GOOD | GOOD |
| 4 | | | | | | |
| Example | 0.43 | 470 | 5.72 × 10⁹ | GOOD | GOOD | GOOD |
| 5 | | | | | | |
| Example | 0.2 | 110 | 1.04 × 10⁹ | GOOD | GOOD | GOOD |
| 6 | | | | | | |
| Comparative | 1.2 | 35 | 5.21 × 10¹⁰ | POOR | POOR | POOR |
| Example | | | | | | |
| 1 | | | | | | |
| Comparative | UNMEASUR- | 10 | UNMEASUR- | POOR | POOR | POOR |
| Example | ABLE | | ABLE | | | |
| 2 | | | | | | |
| Comparative | 1.82 | 520 | 7.37 × 10⁷ | GOOD | POOR | POOR |
| Example | | | | | | |
| 3 | | | | | | |

1. A thermosetting die-bonding film at least having an adhesive layer that is used to fix a semiconductor chip to an adherend, wherein
the breaking energy per unit area is 1 J/mm² or less and the elongation at break is 40% or more to 500% or less at room temperature before thermal setting.

2. The thermosetting die-bonding film according to claim 1, wherein
the adhesive layer contains an epoxy resin and a phenol resin as thermosetting resins and also contains an acrylic resin as a thermoplastic resin, and
when the total weight of the epoxy resin and the phenol resin is regarded as X and the weight of the acrylic resin is regarded as Y, the value of X/(X+Y) is 0.3 or more and less than 0.9.

3. The thermosetting die-bonding film according to claim 2, wherein
at least one of the epoxy resin and the phenol resin contains one type or more of resins having a melting point of 50° C. or more.

4. The thermosetting die-bonding film according to claim 1, wherein
the adhesive layer contains an epoxy resin and a phenol resin as thermosetting resins, an acrylic resin as a thermoplastic resin, and a filler, and
when the total weight of the epoxy resin, the phenol resin, and the acrylic resin is regarded as A and the weight of the filler is regarded as B, the value of B/(A+B) is 0.1 or more to 0.7 or less.

5. The thermosetting die-bonding film according to claim 1, wherein
the tensile storage modulus at −20 to 30° C. before thermal setting is 0.1 to 10 GPa.

6. A dicing die-bonding film, wherein
the thermosetting die-bonding film according claim 1 is laminated on a dicing film including a base and a pressure-sensitive adhesive layer laminated thereon.

7. A semiconductor device manufactured using the thermosetting die-bonding film according to claim 1.

8. A semiconductor device manufactured using the dicing die-bonding film according to claim 6.

9. A dicing die-bonding film, wherein
the thermosetting die-bonding film according claim 2 is laminated on a dicing film including a base and a pressure-sensitive adhesive layer laminated thereon.

10. A dicing die-bonding film, wherein
the thermosetting die-bonding film according claim 4 is laminated on a dicing film including a base and a pressure-sensitive adhesive layer laminated thereon.

11. The thermosetting die-bonding film according to claim 4, wherein the average particle size of the filler is 0.005 to 10 μm.

12. The dicing die-bonding film according to claim 6, wherein the breaking energy per unit area at room temperature during expansion of the bonding part of the dicing film onto a semiconductor wafer is 1.5 to 2 J/mm².
